(19) United States
(12) Patent Application Publication
(10) Pub. No.: US 2015/0311675 A1
(43) Pub. Date: Oct. 29, 2015

(54) VERTICAL-CAVITY SURFACE-EMITTING LASER

(71) Applicant: MURATA MANUFACTURING CO., LTD., Kyoto-fu (JP)

(72) Inventors: Keiji IWATA, Kyoto-fu (JP); Ippei MATSUBARA, Kyoto-fu (JP); Takayuki KONA, Kyoto-fu (JP); Hiroshi WATANABE, Kyoto-fu (JP); Masashi YANAGASE, Kyoto-fu (JP)

(73) Assignee: MURATA MANUFACTURING CO., LTD., Kyoto-fu (JP)

(21) Appl. No.: 14/737,103

(22) Filed: Jun. 11, 2015

Related U.S. Application Data
(63) Continuation of application No. PCT/JP2013/072949, filed on Aug. 28, 2013.

(30) Foreign Application Priority Data
Dec. 28, 2012 (JP) 2012-286537

(51) Int. Cl. H01S 5/183; H01S 5/343; H01S 5/042

(52) U.S. Cl. CPC H01S 5/18394; H01S 5/18383; H01S 5/0425; H01S 5/3432; H01S 5/0421

(57) ABSTRACT

Provided are a base substrate made of a semi-insulating semiconductor; an emission region multilayer unit formed on a surface of the base substrate and including each of an N-type semiconductor contact layer, an N-type DBR layer, an active layer, a P-type semiconductor DBR layer, and a P-type semiconductor contact layer; an anode electrode connected to the P-type semiconductor contact layer; and a cathode electrode formed on a surface side of the base substrate and connected to the N-type semiconductor contact layer. The N-type DBR layer is formed of 15 or more pairs of layers with different compositions laminated on each other. Through this configuration, a vertical-cavity surface-emitting laser that can suppress an occurrence of a defect caused by crystal missing arising from the base substrate can be provided at reduced cost.

### CROSS REFERENCE TO RELATED APPLICATIONS

This application claims benefit of priority to Japanese Patent Application No. 2012-286537 filed on Dec. 28, 2012, and to International Patent Application No. PCT/JP2013/072949 filed on Aug. 28, 2013, the entire content of which is incorporated herein by reference.

### TECHNICAL FIELD

The present disclosure relates to vertical-cavity surface-emitting lasers.

### BACKGROUND

Currently, as one kind of semiconductor lasers, vertical-cavity surface-emitting lasers (VCSELs) are in practical use.

A schematic structure of a vertical-cavity surface-emitting laser is such that, as illustrated in Japanese Unexamined Patent Application Publication (Translation of PCT Application) No. 2003-508928, for example, a first DBR (multilayer distributed Bragg reflector) layer is formed on a base substrate that is made of an N-type semiconductor and that has a cathode electrode formed on a back surface thereof. A first spacer layer is formed on the first DBR layer. An active layer that includes a quantum well is formed on the first spacer layer. A second spacer layer is formed on the active layer. A second DBR layer is formed on the second spacer layer. An anode electrode is formed on the second DBR layer. Then, as a drive signal is applied across the anode electrode and the cathode electrode, a laser beam with a sharp directionality in the direction perpendicular to the substrate (parallel to the direction in which the layers are laminated) is generated.

### SUMMARY

### Technical Problem

Typically, as disclosed in Japanese Unexamined Patent Application Publication (Translation of PCT Application) No. 2003-508928, an N-type semiconductor substrate is used as a base substrate in a semiconductor laser. This is because, when an N-type semiconductor substrate is used, the defect density can be reduced through an effect of impurity hardening caused as impurities with different atomic radii are introduced. A defect in a base substrate is likely to propagate through a semiconductor layer that has been epitaxially grown on the substrate and is thus considered to have a negative influence on the characteristics and the reliability of lasers.

However, with Japanese Unexamined Patent Application Publication (Translation of PCT Application) No. 2003-508928 in which an N-type semiconductor is used for the base substrate, it is more difficult to obtain a large-diameter substrate than a substrate of a versatile semi-insulating semiconductor, and thus there is a problem in that the cost increases. In the meantime, when a semi-insulating semiconductor is used for a base substrate, the defect density of the substrate is higher than in a case in which an N-type semiconductor is used. Therefore, the dislocation density that propagates into a semiconductor layer grown on the substrate increases. In a laser, a semiconductor layer grown on a substrate typically includes an active layer, and thus a defect occurring in the active layer leads to a problem in that the characteristics and the reliability of the laser deteriorate.

Meanwhile, as a technique for suppressing the propagation of a dislocation into a semiconductor layer on a substrate, a method in which a strained superlattice layer is inserted is also being proposed. According to JPN. J. Appl. Phys. Vol. 32 (1993) pp. 614-617, an edge-emitting laser is proposed in which, when InP with large lattice mismatching is formed on an N-type GaAs substrate, an In_{0.65}Ga_{0.35}P layer with lattice mismatching of 2.5% is introduced as a strained layer and the propagation of a dislocation is thus suppressed. However, adding such a strained layer leads to a problem in that the cost of the semiconductor substrate increases.

In addition, Appl. Phys. Lett. 52(7), 543 indicates that the propagation of a dislocation in a semi-insulating GaAs substrate can also be suppressed by an AlAs—GaAs superlattice with small lattice mismatching. In other words, it is indicated that a structure in which an AlAs layer is doped whereas a GaAs layer is not doped can effectively suppress the propagation of a dislocation. However, a layer that is not doped has high resistance, and thus there is a problem in that the characteristics as a semiconductor device deteriorate.

Accordingly, it is an object of the present disclosure to provide a vertical-cavity surface-emitting laser in which the propagation of a dislocation into a semiconductor layer epitaxially grown on a base substrate is suppressed and an occurrence of a defect can be suppressed as a result, while the cost is kept low.

### Solution to Problem

A vertical-cavity surface-emitting laser according to the present disclosure includes a base substrate made of a semi-insulating semiconductor; an emission region multilayer unit that is formed on a surface of the base substrate and that includes each of an N-type semiconductor multilayer film reflection layer, an active layer including a quantum well, and a P-type semiconductor multilayer film reflection layer; an anode electrode connected to the P-type semiconductor multilayer film reflection layer; and a cathode electrode connected to the N-type semiconductor multilayer film reflection layer. The N-type semiconductor multilayer film reflection layer is formed by 15 or more pairs of layers with different compositions laminated on each other.

With this configuration, an occurrence of a deterioration in the laser characteristics due to a crystal defect arising from the base substrate can be suppressed by the N-type semiconductor multilayer film reflection layer in which 15 or more pairs of layers are laminated on each other.

The configuration may be such that the base substrate is made of GaAs; the N-type semiconductor multilayer film reflection layer, the active layer, and the P-type semiconductor multilayer film reflection layer are formed of layers with different composition ratios of Al while the GaAs serves as a base. The N-type semiconductor multilayer film reflection layer, the active layer, and the P-type semiconductor multilayer film reflection layer may be formed by a heterojunction semiconductor.

With this configuration, a vertical-cavity surface-emitting laser with good laser characteristics can be obtained.

The configuration may be such that the number of laminated layers with different compositions in the N-type semiconductor multilayer film reflection layer is equal to or less than 40 pairs.

With this configuration, a low-cost vertical-cavity surface-emitting laser in which a large-diameter, semi-insulating semiconductor substrate that can be easily obtained is used and a decrease in the yield due to the propagation of a dislocation is suppressed can be obtained.

### Advantageous Effects of Disclosure

According to the present disclosure, a vertical-cavity surface-emitting laser that is low-cost and that excels in emission characteristics and reliability can be obtained.

### BRIEF DESCRIPTION OF THE DRAWINGS

FIG. 1 is a plan view of a vertical-cavity surface-emitting laser according to Embodiment 1.

FIG. 2 is a sectional view of the vertical-cavity surface-emitting laser taken along the 2-2 line of FIG. 1.

FIG. 3 is another sectional view of the vertical-cavity surface-emitting laser taken along the 3-3 line of FIG. 1.

FIG. 4 is an enlarged schematic diagram illustrating part of a section of a first semiconductor multilayer film reflection layer.

FIG. 5 is a diagram illustrating a relationship between the number of pairs of AlGaAs layers constituting an N-type semiconductor DBR layer and the direction in which a dislocation propagates.

### DETAILED DESCRIPTION

Hereinafter, a suitable embodiment of a vertical-cavity surface-emitting laser according to the present disclosure will be described with reference to the drawings.

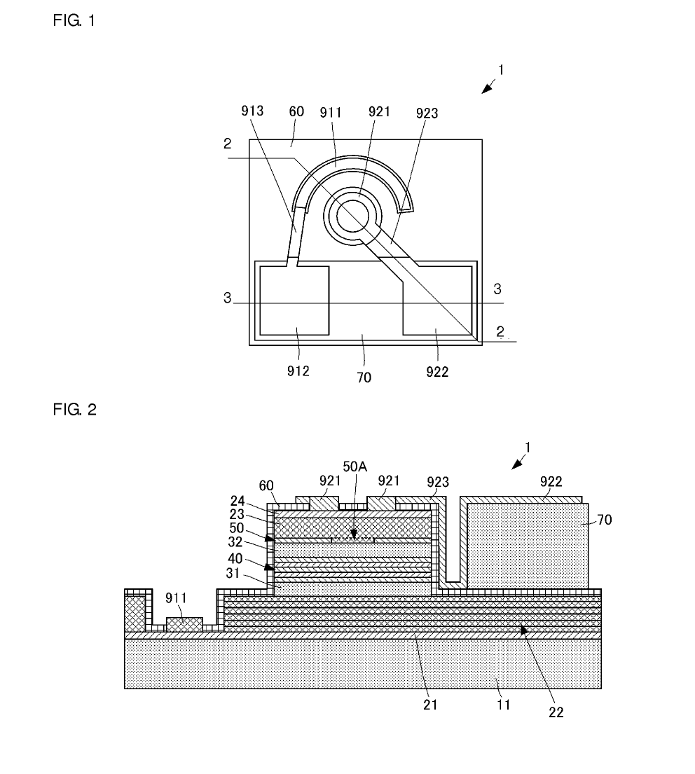

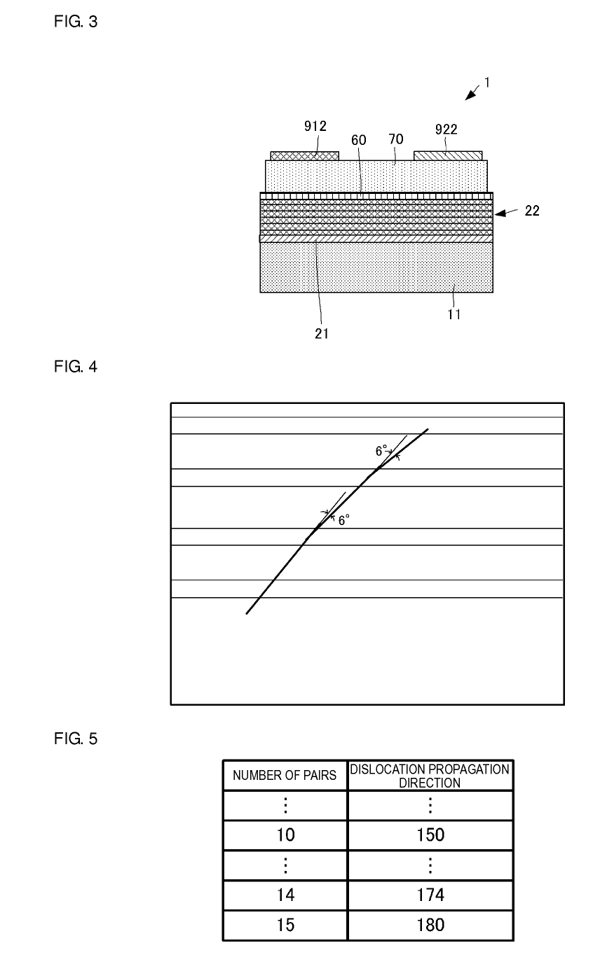

FIG. 1 is a plan view of a vertical-cavity surface-emitting laser according to Embodiment 1. FIG. 2 is a sectional view of the vertical-cavity surface-emitting laser taken along the 2-2 line of FIG. 1. FIG. 3 is another sectional view of the vertical-cavity surface-emitting laser taken along the 3-3 line of FIG. 1.

A vertical-cavity surface-emitting laser 1 is formed of a heterojunction semiconductor and includes a base substrate 11 made of GaAs. The base substrate 11 is a semi-insulating semiconductor substrate made of GaAs. It is preferable that the resistivity of the base substrate 11 be equal to or greater than 1.0×10⁷ Ω·cm.

An N-type semiconductor contact layer 21 is formed on a surface of the base substrate 11. The N-type semiconductor contact layer 21 is made of a compound semiconductor having N-type electrical conductivity.

An N-type DBR (multilayer distributed Bragg reflector) layer 22 is formed on a surface of the N-type semiconductor contact layer 21. This N-type DBR layer corresponds to an N-type semiconductor multilayer film reflection layer. The N-type semiconductor DBR layer 22 is made of an AlGaAs material and formed by a plurality of layers with the composition ratio of Al different from the composition ratio of Ga laminated on each other. In other words, the N-type semiconductor DBR layer is formed by a combination of materials having a band gap greater than the energy of the oscillation wavelength. Specifically, with a high-Al-composition layer with the Al composition of approximately 0.9 and a low-Al-composition layer with the Al composition of approximately 0.1 forming a pair, the N-type semiconductor DBR layer 22 is formed by laminating 15 or more pairs of layers in which each pair includes a high-Al layer and a low-Al layer each having an optical film thickness of ¼λ with respect to the oscillation wavelength λ of the laser. The present embodiment is designed such that λ is 850 nm. Through such a layer configuration, a first reflector for efficiently reflecting a laser beam at a predetermined wavelength is formed. It is to be noted that the N-type semiconductor DBR layer 22 may also function as the N-type semiconductor contact layer 21. In other words, the N-type semiconductor contact layer 21 is not necessarily required.

An N-type semiconductor cladding layer 31 made of an AlGaAs material is formed on a surface of the N-type DBR layer 22. An active layer 40 is formed on a surface of the N-type semiconductor cladding layer 31. The active layer 40 is made of a GaAs material and an AlGaAs material. With AlGaAs layers serving as optical confinement layers having a high band gap, a GaAs layer is formed so as to be interposed therebetween. Through this configuration, the active layer 40 is so configured that a single or a plurality of quantum wells are interposed between the optical confinement layers having a high band gap.

A P-type semiconductor cladding layer 32 made of an AlGaAs material is formed on a surface of each active layer 40. A P-type semiconductor DBR layer 23 is formed on a surface of the P-type semiconductor cladding layer 32. This P-type DBR layer corresponds to a P-type semiconductor multilayer film reflection layer. The P-type semiconductor DBR layer 23 is made of an AlGaAs material and formed by a plurality of layers with the composition ratio of Al different from the composition ratio of Ga laminated on each other. In other words, the P-type semiconductor DBR layer is constituted by a combination of materials having a band gap greater than the energy of the oscillation wavelength. As in the N-type semiconductor DBR layer 22, the P-type semiconductor DBR layer 23 is formed by laminating a plurality of pairs of layers in which each pair includes a high-Al layer and a low-Al layer each having an optical film thickness of ¼λ. Through this configuration, a second reflector for efficiently reflecting a laser beam at a predetermined wavelength is formed.

The P-type semiconductor DBR layer 23 is formed such that the reflectance thereof is somewhat lower than that of the N-type semiconductor DBR layer 31. Although the semiconductor cladding layers are provided so as to sandwich the active layer therebetween, the configuration is not limited thereto. A layer with a film thickness that causes resonance to occur may be provided on the active layer. In addition, the cladding layers do not need to be doped.

An oxidized constriction layer 50 is formed at an interface between the P-type semiconductor cladding layer 32 and the P-type semiconductor DBR layer 23. The oxidized constriction layer 50 is made of an AlGaAs material and has a higher composition ratio of Al relative to Ga than the other layers. The oxidized constriction layer 50 is not formed across the entire interface between the P-type semiconductor cladding layer 32 and the P-type semiconductor DBR layer 23, and a non-formed portion 50A with a predetermined area is present at substantially the center of a formed region.

A P-type semiconductor contact layer 24 is formed on a surface of the P-type semiconductor DBR layer 23. The P-type semiconductor contact layer 24 is formed of a compound semiconductor having P-type electrical conductivity. It is to be noted that the P-type semiconductor DBR layer may also function as the P-type semiconductor contact layer. In other words, the P-type semiconductor contact layer is not necessarily required.

A configuration constituted by the N-type semiconductor contact layer 21, the N-type semiconductor DBR layer 22, the N-type semiconductor cladding layer 31, the active layer 40, the P-type semiconductor cladding layer 32, the P-type semiconductor DBR layer 23, and the P-type semiconductor contact layer 24 described above corresponds to an emission region multilayer unit of the present disclosure.

In such a configuration, the composition ratio of Al relative to Ga is set with respect to the thickness of each layer so that a plurality of quantum wells having a single emission spectral peak wavelength at the position of the antinode of the center of optical standing wave distribution are disposed. Through this configuration, the emission region multilayer unit functions as an emission unit of the vertical-cavity surface-emitting laser 1. Furthermore, as the oxidized constriction layer 50 described above is provided, an electric current can be injected efficiently into an active region, and a lens effect can also be obtained; thus, the power consumption can be reduced.

An anode electrode 921 is formed on the surface of the P-type contact layer 23. The anode electrode 921 is an annular electrode as viewed from the above, as illustrated in FIG. 1. The anode electrode does not necessarily have to be annular, and may, for example, be C-shape with part of the annular shape being cut out or rectangular.

A region in which the N-type semiconductor DBR layer 22 is not formed is provided on the surface of the N-type semiconductor contact layer 21. Such a region is located in the vicinity of a region on the N-type semiconductor DBR layer on which the N-type semiconductor cladding layer 31 is formed.

On such a region, a cathode electrode 911 is formed. The cathode electrode 911 is formed so as to be electrically coupled to the N-type semiconductor contact layer 21. The cathode electrode 911 is an arc-shaped electrode as viewed from the above, as illustrated in FIG. 1.

An insulating film 60 is formed on the surface side of the base substrate 11 so as to cover the outer surface of the components constituting the emission region multilayer unit. The insulating film 60 is formed so as not to cover at least part of the cathode electrode 911 and part of the anode electrode 921. The insulating film 60 is made, for example, of silicon nitride (SiNx).

In the vicinity of the region on the N-type DBR layer on which the N-type semiconductor cladding layer 31 is formed, an insulating layer 70 is formed on a surface of the insulating film 60. The insulating layer 70 is formed, for example, of polyimide.

A cathode pad electrode 912 and an anode pad electrode 922 are formed on a surface of the insulating layer 70 so as to be spaced apart from each other. The insulating layer 70 is formed in the vicinity of the emission region multilayer unit of the vertical-cavity surface-emitting laser 1.

The cathode pad electrode 912 is coupled to the cathode electrode 911 with a cathode wire electrode 913 interposed therebetween. The anode pad electrode 922 is coupled to the anode electrode 921 with an anode wire electrode 923 interposed therebetween.

Through such a configuration, the vertical-cavity surface-emitting laser according to the present embodiment provides the following advantageous effects.

As described above, in the vertical-cavity surface-emitting laser according to the present embodiment, the number of layers having different compositions and lattice constants in the N-type semiconductor DBR layer 22 is equal to or greater than 15 pairs. Through such a configuration, an increase in the dislocation density in the active layer 40 arising from the base substrate 11 made of a semi-insulating semiconductor can be suppressed.

FIG. 4 is an enlarged schematic diagram illustrating part of a section of a first semiconductor multilayer film reflection layer. FIG. 5 is a diagram illustrating a relationship between the number of pairs of AlGaAs layers constituting the N-type semiconductor DBR layer and the direction in which a dislocation propagates.

In FIG. 4, after a GaAs layer serving as a contact layer has been grown on a base substrate, an N-type semiconductor DBR layer is formed. The inventors of the present application have diligently investigated and found that, for each pair of AlGaAs layers with different compositions constituting the N-type semiconductor DBR layer, the growth direction of a dislocation changes by an average of 6° toward the direction parallel to the substrate and becomes substantially parallel (approximately 180°) to the substrate with 15 or more pairs. In other words, as illustrated in FIG. 5, when the number of layers having different compositions in the N-type semiconductor DBR layer is equal to or greater than 15 pairs, a defect in the base substrate can be contained within the N-type semiconductor DBR layer and does not propagate, for example, into an active layer formed on the N-type semiconductor DBR layer.

In a case in which a dislocation caused by a defect in the base substrate reaches the active layer, non-radiative recombination occurs when an electric current is applied to the laser, which leads to a further defect and may cause the emission to stop. Therefore, the reliability noticeably decreases. However, according to the present embodiment, a dislocation arising due to a defect in the base substrate can be prevented from reaching the active layer, and thus the vertical-cavity surface-emitting laser with the favorable laser characteristics and the reliability can be obtained.

As illustrated in FIG. 5, as the number of layers with different compositions constituting the N-type semiconductor DBR layer 22 is set to equal to or greater than 15 pairs, an occurrence of a defect can be greatly reduced. In this manner, with the use of the configuration according to the present embodiment, even if a semi-insulating semiconductor is used for the base substrate 11, an occurrence of a defect arising due to an increase in the dislocation density of the active layer can be greatly reduced. Furthermore, according to the embodiment of the present disclosure, the N-type semiconductor DBR layer suppresses the propagation of a dislocation in the base substrate. In other words, the N-type semiconductor DBR layer also functions as a layer that prevents a dislocation in the base substrate from propagating, and thus a separate dislocation suppression layer does not need to be provided. Thus, the cost of the semiconductor substrate can be reduced.

Accordingly, a versatile, inexpensive semi-insulating semiconductor can be used, and a vertical-cavity surface-emitting laser that excels in the laser characteristics can be implemented through a simple structure.

Although the upper limit of the number of layers in the N-type DBR layer can be set as appropriate with the characteristics of the vertical-cavity surface-emitting laser taken into consideration, the number of layers is preferably, for example, equal to or less than 40 pairs. Through this configuration, the effects described above can be obtained, and at the same time, a vertical-cavity surface-emitting laser that does not cost more than necessary can be obtained.

1. A vertical-cavity surface-emitting laser, comprising:
a base substrate made of a semi-insulating semiconductor;
an emission region multilayer unit formed on a surface of the base substrate, the emission region multilayer unit including each of an N-type semiconductor multilayer film reflection layer, an active layer including a quantum well, and a P-type semiconductor multilayer film reflection layer;
an anode electrode connected to the P-type semiconductor multilayer film reflection layer; and
a cathode electrode connected to the N-type semiconductor multilayer film reflection layer,
wherein the N-type semiconductor multilayer film reflection layer is formed of 15 or more pairs of layers with different compositions laminated on each other.

2. The vertical-cavity surface-emitting laser according to claim 1,
wherein the base substrate is made of GaAs,
wherein the N-type semiconductor multilayer film reflection layer, the active layer, and the P-type semiconductor multilayer film reflection layer are formed of layers with different composition ratios of Al while the GaAs serves as a base, and
wherein the vertical-cavity surface-emitting laser is formed of a heterojunction semiconductor.

3. The vertical-cavity surface-emitting laser according to claim 1,
wherein the number of laminated layers with different compositions in the N-type semiconductor multilayer film reflection layer is equal to or less than 40 pairs.
